(19) United States
(12) Patent Application Publication
(10) Pub. No.: US 2025/0270481 A1
(43) Pub. Date: Aug. 28, 2025

(54) THINNER COMPOSITION

(71) Applicant: DONGWOO FINE-CHEM CO., LTD., Iksan-si (KR)

(72) Inventors: Tae Kyung LEE, Iksan-si (KR); Han Woo PARK, Iksan-si (KR); Ji Min CHUN, Iksan-si (KR); Shiyong YI, Iksan-si (KR); Somin LEE, Iksan-si (KR)

(21) Appl. No.: 19/051,704

(22) Filed: Feb. 12, 2025

(30) Foreign Application Priority Data
Feb. 26, 2024 (KR) 10-2024-0027099

(51) Int. Cl. C11D 7/26; C11D 7/50; G03F 7/20; G03F 7/42

(52) U.S. Cl. CPC C11D 7/265; C11D 7/5022; G03F 7/2004; G03F 7/2028; G03F 7/422; C11D 2111/14

(57) ABSTRACT

A thinner composition containing a propionate compound of a particular structure, an organic solvent with a Hansen solubility parameter by hydrogen bonding force (δh) value of 10 or more, and a lactone-based organic solvent are disclosed. The thinner composition has improved EBR and RRC properties due to excellent solubility for photoresist films and spin-on hardmasks (SOHs). The thinner composition can reduce hump heights and improve coating film uniformity.

### CROSS REFERENCE TO RELATED APPLICATIONS

This application claims priority based on Korean Patent Application No. 10-2024-0027099, filed Feb. 26, 2024, the entire content of which is incorporated herein by reference in its entirety.

### TECHNICAL FIELD

The present invention relates to a thinner composition. More particularly, the present invention relates to a thinner composition with improved EBR and RRC properties due to excellent solubility for various photoresist films and spin-on hardmasks (SOHs), which can reduce hump heights and improve coating film uniformity.

### BACKGROUND ART

In the manufacturing process of semiconductor devices, the process of applying a resist on a wafer, transferring a designed pattern, and then etching it to create a fine circuit pattern such as a semiconductor integrated circuit is called the photolithography process. This is accomplished by applying, exposing, developing, etching, and peeling to realize the desired fine circuit pattern.

During the photolithography process, after the resist is uniformly applied on the surface of the wafer, it is necessary to remove the excess photoresist on the edge or backside of the wafer. This is because the presence of resist on the edge or backside of the wafer can cause various defects in subsequent processes such as etching, ion implantation, etc., resulting in a decrease in the yield of the entire semiconductor device.

In order to remove the resist present on the edge or backside of the wafer, a method of installing spray nozzles on the top and bottom of the edge portion of the wafer and spraying a thinner composition containing an organic solvent through the nozzles on the edge or backside of the wafer has been conventionally used.

For example, Korean Patent Publication No. 10-2013-0125029 discloses a thinner composition that can be used for such wafer processing, comprising: a) methoxypropanolacetic acid, b) methyl 2-hydroxyisobutyrate, and c) 1-methoxy-2-propanol.

Currently, photoresists such as i-line photoresists, KrF photoresists, ArF photoresists, EUV photoresists, and spin-on hardmasks (SOH) used in semiconductor lithography processes have different main components. Therefore, it is necessary to adjust the composition content of organic solvents to improve the solubility and applicability of all of them.

On the other hand, thinner compositions include high polarity components to improve solubility and edge bead removal (EBR) properties for high polarity photoresists. If the polarity is too high, it may accelerate the swelling of the photoresist from the EBR end toward the center of the wafer, resulting in a higher hump height. The high hump height reduces the usable area and increases the defects caused by the hump in the subsequent process, which reduces the yield.

Therefore, there is a need to develop a thinner composition having excellent solubility for various photoresist films and spin-on hardmasks (SOHs) to improve EBR and RRC properties and capable of reducing the hump height and improving the uniformity of the coating film.

### DISCLOSURE

### Technical Problem

An object of the present invention is to provide a thinner composition with improved EBR and RRC properties due to excellent solubility for various photoresist films and spin-on hardmasks (SOHs), which can reduce hump heights and improve coating film uniformity.

### Technical Solution

One embodiment of the present invention relates to a thinner composition comprising:
a compound of the following formula (1);
an organic solvent with a Hansen solubility parameter by hydrogen bonding force (δh) value of 10 or more; and
a lactone-based organic solvent.

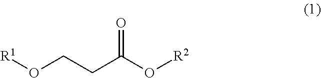

wherein,
R¹ and R² are each independently C₁-C₄ alkyl.

In one embodiment of the present invention, the compound of the above formula (1) may be one or more selected from the group consisting of ethyl 3-methoxypropionate, propyl 3-methoxypropionate, butyl 3-methoxypropionate, ethyl 3-ethoxypropionate, propyl 3-ethoxypropionate, butyl 3-ethoxypropionate, ethyl 3-propoxypropionate, propyl 3-propoxypropionate, butyl 3-propoxypropionate, ethyl 3-butoxypropionate, propyl 3-butoxypropionate, and butyl 3-butoxypropionate.

In one embodiment of the present invention, the organic solvent with a Hansen solubility parameter by hydrogen bonding force (δh) value of 10 or more may be one or more selected from the group consisting of propylene glycol methyl ether, 2-hydroxyisobutyric acid methyl ester, diethylene glycol monobutyl ether, diethylene glycol monoethyl ether, ethyl lactate, butanol, and N,N-dimethylformamide.

In one embodiment of the present invention, the lactone-based organic solvent may be one or more selected from the group consisting of γ-butyrolactone, γ-valerolactone and ε-caprolactone.

The thinner composition according to one embodiment of the present invention may further comprise C₂-C₄ alkylene glycol C₁-C₄ alkyl ether acetate.

In one embodiment of the present invention, C₂-C₄ alkylene glycol C₁-C₄ alkyl ether acetate may be one or more selected from the group consisting of propylene glycol monomethyl ether acetate, propylene glycol monoethyl ether acetate, ethylene glycol monomethyl ether acetate, and ethylene glycol monoethyl ether acetate.

The thinner composition according to one embodiment of the present invention may comprise 45 to 90 wt % of the compound of the above formula (1); 5 to 50 wt % of the organic solvent with a Hansen solubility parameter by hydrogen bonding force (δh) value of 10 or more; and 0.1 to 30 wt % of the lactone-based organic solvent.

The thinner composition according to one embodiment of the present invention may comprise 45 to 90 wt % of the compound of the above formula (1); 5 to 50 wt % of the organic solvent with a Hansen solubility parameter by hydrogen bonding force (δh) value of 10 or more; 0.1 to 30 wt % of the lactone-based organic solvent; and 0.1 to 30 wt % of C₂-C₄ alkylene glycol C₁-C₄ alkyl ether acetate.

The thinner composition according to one embodiment of the present invention may be for one or more of a photoresist film and a spin-on hardmask (SOH).

In one embodiment of the present invention, the photoresist film may be a photoresist film for ArF, KrF, or EUV

### Advantageous Effects

The thinner composition according to the present invention has excellent solubility for photoresist films and spin-on hardmasks (SOHs), resulting in improved EBR and RRC properties. The thinner composition according to the present invention can reduce the hump height and improve the uniformity of the coating film.

### BEST MODE

Hereinafter, the present invention will be described in more detail.

One embodiment of the present invention relates to a thinner composition comprising a propionate compound (A) of a particular structure, an organic solvent (B) with a Hansen solubility parameter by hydrogen bonding force (δh) value of 10 or more, and a lactone-based organic solvent (C).

The thinner composition according to the present invention can be effectively used to reduce the amount of photoresist film and/or spin-on hardmask (SOH) used in semiconductor device and display manufacturing processes or eliminate them.

The thinner composition according to the present invention can reduce the hump height by controlling the polarity and reducing the rate at which the photoresist (PR) is swelled by the thinner from the EBR end toward the center of the wafer. Accordingly, the yield can be improved by increasing the usable area and reducing the defects caused by the hump in subsequent processes.

Further, the thinner composition according to the present invention can reduce the amount of photoresist and/or spin-on hardmask used in the process by increasing the reactivity of the composition forming the photoresist film and/or spin-on hardmask with the substrate surface, allowing a smaller amount to be dispersed more extensively on the substrate.

Furthermore, the thinner composition according to the present invention can improve the uniformity of the coating film.

Accordingly, the thinner composition according to the present invention is suitable for use in the process of forming photoresist films and/or spin-on hardmasks (SOHs) for purposes such as edge bead removal (EBR), back rinse, and resist reduced coating (RRC). For example, the photoresist film may be a photoresist film for ArF, KrF, or EUV

### Propionate Compound (A)

In one embodiment of the present invention, the propionate compound (A) is a component that has a suitable dissolution rate for various types of photoresists while controlling the polarity of the composition to improve EBR images and reduce hump heights.

Specifically, the propionate compound is the compound of the following formula (1).

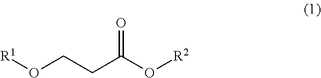

wherein,
R¹ and R² are each independently C₁-C₄ alkyl.

As used herein, C₁-C₄ alkyl means a straight-chain or branched monovalent hydrocarbon comprising 1 to 4 carbons, and includes, for example, but is not limited to, methyl, ethyl, n-propyl, i-propyl, n-butyl, i-butyl, t-butyl, and the like.

In one embodiment of the present invention, in terms of improving EBR and RRC properties, reducing the hump height, and improving the uniformity of the coating film, R¹ and R² may be each independently C₁-C₂ alkyl.

In general, the solubility of the resist is different depending on the type of resist, and the composition of the thinner composition is designed differently in consideration of the target film. However, the thinner composition of the present invention includes the propionate compound of the above structure, which has excellent solubility for all of ArF PR, KrF PR, EUV PR, and SOH (spin on hardmask) organic films, resulting in improved EBR and RRC properties for all of these organic films. Furthermore, the propionate compound can reduce the hump height of the resist coating film that occurs during cleaning of the edge portion and improve the uniformity of the coating film.

In one embodiment of the present invention, examples of the compound of the above formula (1) include ethyl 3-methoxypropionate, propyl 3-methoxypropionate, butyl 3-methoxypropionate, ethyl 3-ethoxypropionate, propyl 3-ethoxypropionate, butyl 3-ethoxypropionate, ethyl 3-propoxypropionate, propyl 3-propoxypropionate, butyl 3-propoxypropionate, ethyl 3-butoxypropionate, propyl 3-butoxypropionate, butyl 3-butoxypropionate, and the like, with ethyl 3-ethoxypropionate being particularly preferred. They can be used alone or in combination of two or more.

In one embodiment of the present invention, the compound of the above formula (1) may be included in an amount of 45 to 90 wt %, preferably from 45 to 75 wt %, based on 100 wt % of the total composition. When the compound of the above formula (1) is used in the above content range, excellent EBR images and reduction in hump heights can be expected. However, if the content of the compound of the above formula (1) is outside the above range, it is difficult to expect straightness of the EBR image, or it may cause high hump heights, which may result in defects in the process.

Organic Solvent (B) with a δh Value of 10 or More

In one embodiment of the present invention, the organic solvent (B) with a Hansen solubility parameter by hydrogen bonding force (δh) value of 10 or more, preferably 10 to 15, interacts with hydroxy groups present in the resin constituting the photoresist or hardmask to improve the dissolution rate, thereby improving film uniformity during photoresist coating, improving EBR images, and reducing hump heights.

In the present invention, the Hansen solubility parameter (δT) is a type of solubility parameter, which is an improved solubility parameter over the previously used Hildebrand solubility parameter. The Hansen solubility parameter (δT) is divided into three components, δd, δp, and δh, and expresses the solubility range of a substance in three-dimensional spatial coordinates. δd represents the solubility parameter by dispersion force, δp represents the solubility parameter by interdipole force, and δh represents the solubility parameter by hydrogen bonding force. For example, the Hansen solubility parameter (δT) (unit: (J/(cm³)^{0.5}) is described and defined in ┌INDUSTRIAL SOLVENTS HANDBOOK┘ (pp. 35-68, Marcel Dekker, Inc., 1996), ┌DIRECTORY OF SOLVENTS┘ (pp. 22-29, Blackie Academic & Professional, 1996), and the like. In the present invention, the Hansen solubility parameters (δT and δd, δp, δh) are calculated using the HSPiP program.

Examples of the organic solvent with a Hansen solubility parameter by hydrogen bonding force (δh) value of 10 or more include propylene glycol methyl ether (δh: 12.1), 2-hydroxyisobutyric acid methyl ester (δh: 13.1), diethylene glycol monobutyl ether (δh: 10.6), diethylene glycol monoethyl ether (δh: 12.2), ethyl lactate (δh: 13.1), butanol (δh: 14.6), N,N-dimethylformamide (δh: 11.3), and the like, which can be used alone or in combination of two or more.

In one embodiment of the present invention, the organic solvent with a Hansen solubility parameter by hydrogen bonding force (δh) value of 10 or more may be included in an amount of 5 to 50 wt %, preferably 15 to 35 wt %, based on 100 wt % of the total composition. When the organic solvent with a Hansen solubility parameter by hydrogen bonding force (δh) value of 10 or more is used in the above content range, photoresist coatings can exhibit excellent EBR images, hump heights, and film uniformity. If the above range is not met, the EBR image of the resist with hydroxy groups may deteriorate, or the hump height may increase, resulting in process failure.

### Lactone-Based Organic Solvent (C)

In one embodiment of the present invention, the lactone-based organic solvent (C) serves to improve RRC performance by remaining on the surface of the substrate for a longer period of time and spreading the photoresist evenly and widely, allowing for extensive coating with a small amount of photoresist without tearing.

The lactone-based organic solvent has a structure with an ester functional group in a hydrocarbon ring and generally has high polarity. Depending on the number of carbons forming the ring, the lactone-based organic solvents can have a three-membered, four-membered, five-membered, six-membered, seven-membered, and larger lactone structures, but five-membered or larger lactone compounds with a stable bonding angle are preferred. For example, the lactone-based organic solvents include γ-butyrolactone, γ-valerolactone, ε-caprolactone, and the like, which can be used alone or in combination of two or more.

In one embodiment of the present invention, the lactone-based organic solvent may be included in an amount of 0.1 to 30 wt %, preferably 1 to 20 wt %, based on 100 wt % of the total thinner composition. When the lactone-based organic solvent is used in the above content range, improved RRC performance may be achieved. When the lactone-based organic solvent is used in an amount below the content range, the RRC performance may be degraded, and when used in an amount above the content range, it may be difficult to show straight EBR images or high hump heights may be exhibited.

C₂-C₄ alkylene glycol C₁-C₄ Alkyl Ether Acetate (D)

The thinner composition according to one embodiment of the present invention may further comprise C₂-C₄ alkylene glycol C₁-C₄ alkyl ether acetate (D).

In one embodiment of the present invention, the C₂-C₄ alkylene glycol C₁-C₄ alkyl ether acetate has good solubility for various types of photoresists and serves to improve the uniformity of the photoresist film.

Examples of the C₂-C₄ alkylene glycol C₁-C₄ alkyl ether acetate include propylene glycol monomethyl ether acetate, propylene glycol monoethyl ether acetate, ethylene glycol monomethyl ether acetate, ethylene glycol monoethyl ether acetate, and the like. In particular, it is preferably selected from propylene glycol monomethyl ether acetate and propylene glycol monoethyl ether acetate. They can be used alone or in combination of two or more.

In one embodiment of the present invention, the C₂-C₄ alkylene glycol C₁-C₄ alkyl ether acetate may be included in an amount of 30 wt % or less, such as 0.1 to 30 wt %, preferably 1 to 15 wt %, based on 100 wt % of the total thinner composition. When the C₂-C₄ alkylene glycol C₁-C₄ alkyl ether acetate is used in the above content range, film uniformity and EBR image can be improved and hump height can be reduced when coating a photoresist. If the content of the C₂-C₄ alkylene glycol C₁-C₄ alkyl ether acetate exceeds the above content range, the photoresist may have poor EBR image or exhibit high hump heights.

The thinner composition according to one embodiment of the present invention may further comprise additives such as surfactants, pH adjusters, and the like as required.

As surfactants, silicone-based surfactants, non-ionic surfactants, and the like may be used.

The thinner composition according to one embodiment of the present invention may comprise 45 to 90 wt % of the compound of the above formula (1); 5 to 50 wt % of the organic solvent with a Hansen solubility parameter by hydrogen bonding force (δh) value of 10 or more; and 0.1 to 30 wt % of the lactone-based organic solvent.

The thinner composition according to one embodiment of the present invention may comprise 45 to 90 wt % of the compound of the above formula (1); 5 to 50 wt % of the organic solvent with a Hansen solubility parameter by hydrogen bonding force (δh) value of 10 or more; 0.1 to 30 wt % of the lactone-based organic solvent; and 0.1 to 30 wt % of C₂-C₄ alkylene glycol C₁-C₄ alkyl ether acetate.

One embodiment of the present invention relates to a method of treating a substrate using the thinner composition described above.

A method of treating a substrate according to one embodiment of the present invention may comprise the steps of modifying the substrate with the thinner composition, and applying a photoresist or SOH on the modified substrate.

By performing the substrate modification step prior to applying the photoresist or SOH, the removal process can be performed effectively without causing tailing phenomenon in the edge bead removing (EBR) process, excellent coating uniformity can be maintained, and the reducing resist consumption (RRC) effect, which enables coating a wafer with a small amount of photoresist or SOH, can be maximized.

The modification step may be performed by applying the thinner composition according to the present invention in a conventional manner. For example, the modification step may be performed by spraying the thinner composition onto the center of a stationary substrate and then rotating the substrate so that the sprayed thinner composition is spread over the entire surface of the substrate. The amount of spraying may be from 0.1 cc to 5 cc.

The photoresist used in the application step may be at least one of photoresists for ArF, KrF and EUV Further, the SOH used in the application step may be at least one of C—SOH and Si—SOH. When C—SOH is used, stability at high temperature is excellent, and when Si—SOH is used, optical properties are easily controllable.

The method of treating the substrate may further comprise, after the step of applying the photoresist or SOH, the step of treating the substrate with the thinner composition according to the present invention.

By treating the substrate with the thinner composition after the application step of the photoresist or SOH, excess photoresist film or SOH applied on the edge or backside of the substrate can be quickly and effectively removed prior to the exposure process.

A method of treating a substrate according to one embodiment of the present invention may comprise the steps of applying a photoresist or SOH on a substrate to form a film, and treating the film with the thinner composition according to the present invention.

By treating the substrate with the thinner composition after the application step of the photoresist or SOH, excess photoresist film or SOH applied on the edge or backside of the substrate can be quickly and effectively removed prior to the exposure process.

The method of treating the substrate may comprise the steps of treating the SOH-coated substrate with the thinner composition, then applying a photoresist, and then treating the substrate again with the thinner composition.

By applying the photoresist and subsequently treating the substrate again with the thinner composition in the above steps, excess photoresist and SOH applied on the edge or backside of the substrate can be quickly and effectively removed prior to the exposure process.

Hereinafter, the present invention will be described more specifically by means of examples, comparative examples, and experimental examples. These examples, comparative examples, and experimental examples are intended to illustrate the present invention only, and it is obvious to those skilled in the art that the scope of the present invention is not limited to them.

### EXAMPLES AND COMPARATIVE EXAMPLES: PREPARATION OF THINNER COMPOSITIONS

Thinner compositions were prepared by mixing the components in the composition of Table 1 below (unit: wt %).

TABLE 1

| | (A) | | (B) | | | (C) | | | (D) | (E) | | | | |
|---|---|---|---|---|---|---|---|---|---|---|---|---|---|---|
| | A-1 | A-2 | B-1 | B-2 | B-3 | C-1 | C-2 | C-3 | D-1 | E-1 | E-2 | E-3 | E-4 | E-5 |
| Example | 50 | | 30 | | | 10 | | | 10 | | | | | |
| 1 | | | | | | | | | | | | | | |
| Example | | 50 | 30 | | | 10 | | | 10 | | | | | |
| 2 | | | | | | | | | | | | | | |
| Example | 50 | | | 30 | | 10 | | | 10 | | | | | |
| 3 | | | | | | | | | | | | | | |
| Example | 50 | | | | 30 | 10 | | | 10 | | | | | |
| 4 | | | | | | | | | | | | | | |
| Example | 50 | | 30 | | | | 10 | | 10 | | | | | |
| 5 | | | | | | | | | | | | | | |
| Example | 50 | | 30 | | | | | 10 | 10 | | | | | |
| 6 | | | | | | | | | | | | | | |
| Example | 45 | | 35 | | | 10 | | | 10 | | | | | |
| 7 | | | | | | | | | | | | | | |
| Example | 75 | | 5 | | | 10 | | | 10 | | | | | |
| 8 | | | | | | | | | | | | | | |
| Example | 90 | | 5 | | | 1 | | | 4 | | | | | |
| 9 | | | | | | | | | | | | | | |
| Example | 65 | | 15 | | | 10 | | | 10 | | | | | |
| 10 | | | | | | | | | | | | | | |
| Example | 45 | | 50 | | | 4 | | | 1 | | | | | |
| 11 | | | | | | | | | | | | | | |
| Example | 59.9 | | 30 | | | 0.1 | | | 10 | | | | | |
| 12 | | | | | | | | | | | | | | |
| Example | 59 | | 30 | | | 1 | | | 10 | | | | | |
| 13 | | | | | | | | | | | | | | |
| Example | 45 | | 30 | | | 20 | | | 5 | | | | | |
| 14 | | | | | | | | | | | | | | |
| Example | 45 | | 20 | | | 30 | | | 5 | | | | | |
| 15 | | | | | | | | | | | | | | |
| Example | 59.9 | | 30 | | | 10 | | | 0.1 | | | | | |
| 16 | | | | | | | | | | | | | | |
| Example | 59 | | 30 | | | 10 | | | 1 | | | | | |
| 17 | | | | | | | | | | | | | | |
| Example | 45 | | 30 | | | 10 | | | 15 | | | | | |
| 18 | | | | | | | | | | | | | | |
| Example | 45 | | 20 | | | 5 | | | 30 | | | | | |
| 19 | | | | | | | | | | | | | | |
| Example | 60 | | 30 | | | 10 | | | | | | | | |
| 20 | | | | | | | | | | | | | | |
| Example | | 60 | 30 | | | 10 | | | | | | | | |
| 21 | | | | | | | | | | | | | | |
| Example | 61 | | 4 | | | 10 | | | 25 | | | | | |
| 22 | | | | | | | | | | | | | | |
| Example | 45 | | 51 | | | 3 | | | 1 | | | | | |
| 23 | | | | | | | | | | | | | | |
| Example | 59.95 | | 30 | | | 0.05 | | | 10 | | | | | |
| 24 | | | | | | | | | | | | | | |
| Example | 45 | | 20 | | | 31 | | | 4 | | | | | |
| 25 | | | | | | | | | | | | | | |
| Example | 50 | | 30 | | | 10 | | | 31 | | | | | |
| 26 | | | | | | | | | | | | | | |
| Example | 44 | | 36 | | | 10 | | | 10 | | | | | |
| 27 | | | | | | | | | | | | | | |
| Example | 91 | | 5 | | | 1 | | | 3 | | | | | |
| 28 | | | | | | | | | | | | | | |
| Comparative | 60 | | 30 | | | | | | 10 | | | | | |
| Example 1 | | | | | | | | | | | | | | |
| Comparative | 80 | | | | | 10 | | | 10 | | | | | |
| Example 2 | | | | | | | | | | | | | | |
| Comparative | | | 50 | | | 20 | | | 30 | | | | | |
| Example 3 | | | | | | | | | | | | | | |
| Comparative | 50 | | 30 | | | | | | 10 | 10 | | | | |
| Example 4 | | | | | | | | | | | | | | |
| Comparative | 50 | | 30 | | | | | | 10 | | 10 | | | |
| Example 5 | | | | | | | | | | | | | | |
| Comparative | 50 | | 30 | | | | | | 10 | | | 10 | | |
| Example 6 | | | | | | | | | | | | | | |
| Comparative | 50 | | 30 | | | | | | 10 | | | | 10 | |
| Example 7 | | | | | | | | | | | | | | |
| Comparative | 50 | | 30 | | | | | | 10 | | | | | 10 |
| Example 8 | | | | | | | | | | | | | | |

(A) Propionate compound
A-1: Methyl 3-methoxypropionate
A-2: Ethyl 3-ethoxypropionate
(B) Organic solvent with a δh value of 10 or more
B-1: Propylene glycol monomethyl ether (δh: 12.1)
B-2: 2-hydroxyisobutyric acid methyl ester (δh: 13.1)
B-3: Ethyl lactate (δh: 13.1)
(C) Lactone-based organic solvent
C-1: γ-butyrolactone
C-2: γ-valerolactone
C-3: ε- caprolactone
(D) C₂-C₄ alkylene glycol C₁-C₄ alkyl ether acetate
D-1: propylene glycol monomethyl ether acetate
(E) Other organic solvent
E-1: n-butyl acetate
E-2: Methyl ethyl ketone
E-3: N-methyl-2-pyrrolidone
E-4: Cyclohexanone
E-5: 2-heptanone

### Experimental Example 1

The thinner compositions prepared in the above examples and comparative examples were evaluated using a 12 inch Track (ACT-12, TEL) with the photoresist and SOH shown in Table 2 below under the conditions shown in Table 3 below.

The results are shown in Tables 4 to 6 below.

TABLE 2

| Category | PR type |
|---|---|
| PR 1 | NTD PR A for EUV |
| PR 2 | NTD PR B for EUV |
| PR 3 | PR C for ArF |
| PR 4 | PR D for KrF |
| SOH | Universal SOH |

TABLE 3

| Performance | | Time | Rotational Speed | |
|---|---|---|---|---|
| Evaluation Step | | (seconds) | (rpm) | Description |
| 1 | Thinner | 3 | 0 | 4.0 cc of thinner |
| | Application | | | |
| 2 | Thinner | 5 | 2000 | |
| | Coating | | | |
| 3 | PR Spray | 5 | 500 | 0.5 cc to 4 cc of PR |
| | Conditions | | | |
| 4 | PR Coating | 20 | 500~2000 | Adjust the film |
| | | | | thickness according to |
| | | | | the purpose of each |
| | | | | type of PR |
| 5 | EBR | 9 | 800 | Thinner spraying |
| | Conditions | | | speed 15 mL/min |
| 6 | Soft Baking | 50~60 | — | Temperature 90 to |
| | | | | 130° C. depending |
| | | | | on PR |

### (1) Reducing Resist Coating (RRC) Performance Evaluation

Prior to applying each photoresist on a 12-inch silicon wafer, 4.0 cc of each thinner composition was applied for 3 seconds in a stationary state, followed by rapid rotation of the substrate at 2000 rpm for 5 seconds to distribute the thinner composition over the entire surface of the wafer. The RRC performance evaluation was then conducted to measure the application distribution and consumption of the photoresist according to the thinner composition by applying 0.8 cc and 0.6 cc, respectively, for the photoresists shown in Table 2 above.

The RRC performance was evaluated according to the following evaluation criteria.

### <RRC Evaluation Criteria>

x: less than 80% of photoresist is applied on the wafer as a result of RRC
Δ: 80% to less than 95% of photoresist is applied on the wafer as a result of RRC
◯: 95% or more of photoresist is applied on the wafer as a result of RRC, but there are stains
⊚: 95% or more of photoresist is applied on the wafer as a result of RRC, and there are no stains

### (2) Edge Bead Removal (EBR) Performance Evaluation

A 12-inch silicon wafer substrate was coated with the photoresist or SOH listed in Table 2 above on the entire surface of the wafer under the evaluation conditions in Table 3 above, and an EBR test was conducted to remove excess photoresist at the edge using each thinner composition under the conditions listed in the 5th step of Table 3 above.

The EBR test was performed for four PRs and one SOH. The thinner compositions of the examples and comparative examples were supplied at a constant pressure from a pressurized canister equipped with a pressure gauge, and a total of 2.2 cc of the thinner was sprayed at a constant pressure during the EBR process. The evaluated substrates were examined under an optical microscope at 400× and 1,000× magnifications to check the straightness, uniformity, and tailing of the EBR line to evaluate the EBR according to the following evaluation criteria.

In addition, for the evaluation sample that shows the straightness and uniformity of the EBR line, the film thicknesses at 35 m inward and 35 m outward from the EBR line of the photoresist film were measured using a film thickness gauge (Dektak 6M, Veeco) to derive the maximum film thickness value. Then, the average thickness of the photoresist film was excluded to calculate the hump height, which was evaluated according to the following evaluation criteria.

### <EBR Evaluation Criteria>

X: EBR line on the photoresist film is not uniform and tailing phenomenon occurs after EBR
Δ: No straightness and uniformity of EBR line on the photoresist film after EBR
◯: Straight but not uniform EBR line on the photoresist film after EBR
⊚: Straight and uniform EBR line on the photoresist film after EBR

### <Hump Height Evaluation Criteria>

x: Hump height is 1000 Å or more
Δ: Hump height is 500 Å to less than 1000 Å
◯: Hump height is 100 Å to less than 500 Å
⊚: Hump height is less than 100 Å

### (3) Uniformity Evaluation

Using the thinner compositions prepared in the examples and comparative examples, uniformity evaluation was performed by measuring film thicknesses at 61 points on the front surface of the wafer after coating the photoresist or SOH in Table 2 above, and calculating the standard deviation. Before applying the photoresist on the 12-inch silicon wafer, 4.0 cc of each thinner composition was applied for 3 seconds in a stationary state, followed by a 5-second substrate rotation at 2000 rpm to distribute the thinner over the entire surface of the wafer, as shown in Table 3. 1.0 cc of photoresist or SOH was coated, respectively. Uniformity was evaluated according to the following evaluation criteria.

### <Uniformity Evaluation Criteria>

x: Standard deviation 6 value is 100 Å or more for PR film thicknesses at 61 points
Δ: Standard deviation σ value is 50 Å to less than 100 Å for PR film thicknesses at 61 points
◯: Standard deviation σ value is 20 Å to less than 50 Å for PR film thicknesses at 61 points
⊚: Standard deviation σ value is less than 20 Å for PR film thicknesses at 61 points

TABLE 4

| | PR 1 | | | | | PR 2 | | | | |
|---|---|---|---|---|---|---|---|---|---|---|
| | RRC | RRC | | Hump | | RRC | RRC | | Hump | |
| | (0.8 cc) | (0.6 cc) | EBR | height | Uniformity | (0.8 cc) | (0.6 cc) | EBR | height | Uniformity |
| Example | ⊚ | ⊚ | ◯ | ◯ | ⊚ | ⊚ | ⊚ | ◯ | ◯ | ⊚ |
| 1 | | | | | | | | | | |
| Example | ⊚ | ⊚ | ◯ | ◯ | ⊚ | ⊚ | ⊚ | ◯ | ◯ | ⊚ |
| 2 | | | | | | | | | | |
| Example | ⊚ | ⊚ | ◯ | ◯ | ⊚ | ⊚ | ⊚ | ◯ | ◯ | ⊚ |
| 3 | | | | | | | | | | |
| Example | ⊚ | ⊚ | ◯ | ◯ | ⊚ | ⊚ | ⊚ | ◯ | ◯ | ⊚ |
| 4 | | | | | | | | | | |
| Example | ⊚ | ⊚ | ◯ | ◯ | ⊚ | ⊚ | ⊚ | ◯ | ◯ | ⊚ |
| 5 | | | | | | | | | | |
| Example | ⊚ | ⊚ | ◯ | ◯ | ⊚ | ⊚ | ⊚ | ◯ | ◯ | ⊚ |
| 6 | | | | | | | | | | |
| Example | ⊚ | ⊚ | ◯ | ◯ | ◯ | ⊚ | ⊚ | ◯ | ◯ | ◯ |
| 7 | | | | | | | | | | |
| Example | ⊚ | ⊚ | ◯ | ◯ | ⊚ | ⊚ | ⊚ | ◯ | ◯ | ⊚ |
| 8 | | | | | | | | | | |
| Example | ⊚ | ◯ | ◯ | ◯ | ◯ | ⊚ | ◯ | ◯ | ◯ | ◯ |
| 9 | | | | | | | | | | |
| Example | ⊚ | ⊚ | ◯ | ◯ | ⊚ | ⊚ | ⊚ | ◯ | ◯ | ⊚ |
| 10 | | | | | | | | | | |
| Example | ⊚ | ⊚ | ◯ | ◯ | ◯ | ⊚ | ⊚ | ◯ | ◯ | ◯ |
| 11 | | | | | | | | | | |
| Example | ◯ | Δ | ◯ | ◯ | ⊚ | ◯ | Δ | ◯ | ◯ | ⊚ |
| 12 | | | | | | | | | | |
| Example | ⊚ | ◯ | ◯ | ◯ | ⊚ | ⊚ | ◯ | ◯ | ◯ | ⊚ |
| 13 | | | | | | | | | | |
| Example | ⊚ | ⊚ | ◯ | ◯ | ◯ | ⊚ | ⊚ | ◯ | ◯ | ◯ |
| 14 | | | | | | | | | | |
| Example | ⊚ | ⊚ | ◯ | ◯ | ◯ | ⊚ | ⊚ | ◯ | ◯ | ◯ |
| 15 | | | | | | | | | | |
| Example | ⊚ | ⊚ | ◯ | ◯ | ⊚ | ⊚ | ⊚ | ◯ | ◯ | ⊚ |
| 16 | | | | | | | | | | |
| Example | ⊚ | ⊚ | ◯ | ◯ | ⊚ | ⊚ | ⊚ | ◯ | ◯ | ⊚ |
| 17 | | | | | | | | | | |
| Example | ⊚ | ⊚ | ◯ | ◯ | ⊚ | ⊚ | ⊚ | ◯ | ◯ | ⊚ |
| 18 | | | | | | | | | | |
| Example | ⊚ | ⊚ | ◯ | ◯ | ◯ | ⊚ | ⊚ | ◯ | ◯ | ◯ |
| 19 | | | | | | | | | | |
| Example | ⊚ | ⊚ | ◯ | ◯ | ◯ | ⊚ | ⊚ | ◯ | ◯ | ◯ |
| 20 | | | | | | | | | | |
| Example | ⊚ | ⊚ | ◯ | ◯ | ◯ | ⊚ | ⊚ | ◯ | ◯ | ◯ |
| 21 | | | | | | | | | | |
| Example | ⊚ | ⊚ | Δ | Δ | Δ | ⊚ | ⊚ | Δ | Δ | Δ |
| 22 | | | | | | | | | | |
| Example | ⊚ | ⊚ | Δ | Δ | X | ⊚ | ⊚ | Δ | Δ | X |
| 23 | | | | | | | | | | |
| Example | Δ | Δ | ◯ | ◯ | ◯ | Δ | Δ | ◯ | ◯ | ◯ |
| 24 | | | | | | | | | | |
| Example | ⊚ | ⊚ | Δ | Δ | Δ | ⊚ | ⊚ | Δ | Δ | Δ |
| 25 | | | | | | | | | | |
| Example | ⊚ | ⊚ | Δ | Δ | ◯ | ⊚ | ⊚ | Δ | Δ | ◯ |
| 26 | | | | | | | | | | |
| Example | ⊚ | ⊚ | Δ | Δ | Δ | ⊚ | ⊚ | Δ | Δ | Δ |
| 27 | | | | | | | | | | |
| Example | ⊚ | ◯ | Δ | Δ | Δ | ⊚ | ◯ | Δ | Δ | Δ |
| 28 | | | | | | | | | | |
| Comparative | X | X | ◯ | ◯ | ◯ | X | X | ◯ | ◯ | ◯ |
| Example 1 | | | | | | | | | | |
| Comparative | ⊚ | ⊚ | X | X | Δ | ⊚ | ⊚ | X | X | Δ |
| Example 2 | | | | | | | | | | |
| Comparative | ⊚ | ⊚ | X | X | Δ | ⊚ | ⊚ | X | X | Δ |
| Example 3 | | | | | | | | | | |
| Comparative | X | X | Δ | Δ | Δ | X | X | Δ | Δ | Δ |
| Example 4 | | | | | | | | | | |
| Comparative | X | X | Δ | Δ | Δ | X | X | Δ | Δ | Δ |
| Example 5 | | | | | | | | | | |
| Comparative | X | X | Δ | Δ | Δ | X | X | Δ | Δ | Δ |
| Example 6 | | | | | | | | | | |
| Comparative | Δ | X | Δ | Δ | Δ | Δ | X | Δ | Δ | Δ |
| Example 7 | | | | | | | | | | |
| Comparative | X | X | Δ | Δ | Δ | X | X | Δ | Δ | Δ |
| Example 8 | | | | | | | | | | |

TABLE 5

| | PR 3 | | | | | PR 4 | | | | |
|---|---|---|---|---|---|---|---|---|---|---|
| | RRC | RRC | | Hump | | RRC | RRC | | Hump | |
| | (0.8 cc) | (0.6 cc) | EBR | height | Uniformity | (0.8 cc) | (0.6 cc) | EBR | height | Uniformity |
| Example | ⊚ | ⊚ | ⊚ | ◯ | ⊚ | ⊚ | ⊚ | ⊚ | ⊚ | ⊚ |
| 1 | | | | | | | | | | |
| Example | ⊚ | ⊚ | ⊚ | ◯ | ⊚ | ⊚ | ⊚ | ⊚ | ⊚ | ⊚ |
| 2 | | | | | | | | | | |
| Example | ⊚ | ⊚ | ⊚ | ◯ | ⊚ | ⊚ | ⊚ | ⊚ | ⊚ | ⊚ |
| 3 | | | | | | | | | | |
| Example | ⊚ | ⊚ | ⊚ | ◯ | ⊚ | ⊚ | ⊚ | ⊚ | ⊚ | ⊚ |
| 4 | | | | | | | | | | |
| Example | ⊚ | ⊚ | ⊚ | ◯ | ⊚ | ⊚ | ⊚ | ⊚ | ⊚ | ⊚ |
| 5 | | | | | | | | | | |
| Example | ⊚ | ⊚ | ⊚ | ◯ | ⊚ | ⊚ | ⊚ | ⊚ | ⊚ | ⊚ |
| 6 | | | | | | | | | | |
| Example | ⊚ | ⊚ | ⊚ | ◯ | ◯ | ⊚ | ⊚ | ⊚ | ⊚ | ◯ |
| 7 | | | | | | | | | | |
| Example | ⊚ | ⊚ | ⊚ | ◯ | ⊚ | ⊚ | ⊚ | ⊚ | ⊚ | ⊚ |
| 8 | | | | | | | | | | |
| Example | ⊚ | ◯ | ◯ | ◯ | ◯ | ⊚ | ◯ | ◯ | ◯ | ◯ |
| 9 | | | | | | | | | | |
| Example | ⊚ | ⊚ | ⊚ | ◯ | ⊚ | ⊚ | ⊚ | ⊚ | ⊚ | ⊚ |
| 10 | | | | | | | | | | |
| Example | ⊚ | ⊚ | ⊚ | ◯ | ◯ | ⊚ | ⊚ | ⊚ | ⊚ | ◯ |
| 11 | | | | | | | | | | |
| Example | ◯ | Δ | ⊚ | ◯ | ⊚ | ◯ | Δ | ⊚ | ⊚ | ⊚ |
| 12 | | | | | | | | | | |
| Example | ⊚ | ◯ | ⊚ | ◯ | ⊚ | ⊚ | ◯ | ⊚ | ⊚ | ⊚ |
| 13 | | | | | | | | | | |
| Example | ⊚ | ⊚ | ⊚ | ◯ | ◯ | ⊚ | ⊚ | ⊚ | ⊚ | ◯ |
| 14 | | | | | | | | | | |
| Example | ⊚ | ⊚ | ⊚ | ◯ | ◯ | ⊚ | ⊚ | ⊚ | ⊚ | ◯ |
| 15 | | | | | | | | | | |
| Example | ⊚ | ⊚ | ⊚ | ◯ | ⊚ | ⊚ | ⊚ | ⊚ | ◯ | ⊚ |
| 16 | | | | | | | | | | |
| Example | ⊚ | ⊚ | ⊚ | ◯ | ⊚ | ⊚ | ⊚ | ⊚ | ◯ | ⊚ |
| 17 | | | | | | | | | | |
| Example | ⊚ | ⊚ | ⊚ | ◯ | ⊚ | ⊚ | ⊚ | ⊚ | ◯ | ⊚ |
| 18 | | | | | | | | | | |
| Example | ⊚ | ⊚ | ⊚ | ◯ | ◯ | ⊚ | ⊚ | ⊚ | ◯ | ◯ |
| 19 | | | | | | | | | | |
| Example | ⊚ | ⊚ | ⊚ | ◯ | ◯ | ⊚ | ⊚ | ⊚ | ◯ | ◯ |
| 20 | | | | | | | | | | |
| Example | ⊚ | ⊚ | ⊚ | ◯ | ◯ | ⊚ | ⊚ | ⊚ | ◯ | ◯ |
| 21 | | | | | | | | | | |
| Example | ⊚ | ⊚ | Δ | Δ | Δ | ⊚ | ⊚ | Δ | Δ | Δ |
| 22 | | | | | | | | | | |
| Example | ⊚ | ⊚ | Δ | Δ | X | ⊚ | ⊚ | Δ | Δ | X |
| 23 | | | | | | | | | | |
| Example | Δ | Δ | ◯ | ◯ | ◯ | Δ | Δ | ◯ | ◯ | ◯ |
| 24 | | | | | | | | | | |
| Example | ⊚ | ⊚ | Δ | Δ | Δ | ⊚ | ⊚ | Δ | Δ | Δ |
| 25 | | | | | | | | | | |
| Example | ⊚ | ⊚ | Δ | Δ | ◯ | ⊚ | ⊚ | Δ | Δ | ◯ |
| 26 | | | | | | | | | | |
| Example | ⊚ | ⊚ | Δ | Δ | Δ | ⊚ | ⊚ | Δ | Δ | Δ |
| 27 | | | | | | | | | | |
| Example | ⊚ | ◯ | Δ | Δ | Δ | ⊚ | ◯ | Δ | Δ | Δ |
| 28 | | | | | | | | | | |
| Comparative | X | X | ◯ | ◯ | ◯ | X | X | ◯ | ◯ | ◯ |
| Example 1 | | | | | | | | | | |
| Comparative | ⊚ | ⊚ | X | X | Δ | ⊚ | ⊚ | X | X | Δ |
| Example 2 | | | | | | | | | | |
| Comparative | ⊚ | ⊚ | X | X | Δ | ⊚ | ⊚ | X | X | Δ |
| Example 3 | | | | | | | | | | |
| Comparative | X | X | X | X | Δ | X | X | X | X | Δ |
| Example 4 | | | | | | | | | | |
| Comparative | X | X | X | X | Δ | X | X | X | X | Δ |
| Example 5 | | | | | | | | | | |
| Comparative | X | X | X | X | Δ | X | X | X | X | Δ |
| Example 6 | | | | | | | | | | |
| Comparative | Δ | X | Δ | Δ | Δ | X | X | Δ | Δ | Δ |
| Example 7 | | | | | | | | | | |
| Comparative | X | X | X | X | Δ | X | X | X | X | Δ |
| Example 8 | | | | | | | | | | |

TABLE 6

SOH

| | EBR | Hump height |
|---|---|---|
| Example 1 | ⊚ | ⊚ |
| Example 2 | ⊚ | ⊚ |
| Example 3 | ⊚ | ⊚ |
| Example 4 | ⊚ | ⊚ |
| Example 5 | ⊚ | ⊚ |
| Example 6 | ⊚ | ⊚ |
| Example 7 | ⊚ | ⊚ |
| Example 8 | ⊚ | ⊚ |
| Example 9 | ◯ | ◯ |
| Example 10 | ⊚ | ⊚ |
| Example 11 | ⊚ | ⊚ |
| Example 12 | ⊚ | ⊚ |
| Example 13 | ⊚ | ⊚ |
| Example 14 | ⊚ | ⊚ |
| Example 15 | ⊚ | ⊚ |
| Example 16 | ⊚ | ◯ |
| Example 17 | ⊚ | ◯ |
| Example 18 | ⊚ | ◯ |
| Example 19 | ⊚ | ◯ |
| Example 20 | ⊚ | ◯ |
| Example 21 | ⊚ | ◯ |
| Example 22 | Δ | Δ |
| Example 23 | Δ | Δ |
| Example 24 | ◯ | ◯ |
| Example 25 | Δ | Δ |
| Example 26 | Δ | Δ |
| Example 27 | Δ | Δ |
| Example 28 | Δ | Δ |
| Comparative Example 1 | Δ | Δ |
| Comparative Example 2 | X | X |
| Comparative Example 3 | X | X |
| Comparative Example 4 | X | X |
| Comparative Example 5 | X | X |
| Comparative Example 6 | X | X |
| Comparative Example 7 | Δ | Δ |
| Comparative Example 8 | X | X |

As shown in Tables 4 to 6 above, it was found that the thinner compositions of Examples 1 to 28 according to the present invention, which include a propionate compound of a specific structure, an organic solvent with a Hansen solubility parameter by hydrogen bonding force (δh) value of 10 or more and a lactone-based organic solvent, have excellent EBR properties for photoresist films and spin-on hard masks (SOH), and can reduce the hump height. Furthermore, the thinner compositions of Examples 1 to 28 have excellent RRC properties for photoresist films and can improve the uniformity of the coating film.

On the other hand, the thinner compositions of Comparative Examples 1 to 8, which do not include the propionate compound of a specific structure, the organic solvent with a Hansen solubility parameter by hydrogen bonding force (δh) value of 10 or more, or the lactone-based organic solvent were found to have inferior EBR and/or RRC properties, low ability to reduce hump height, and poor uniformity of the coating film.

Although particular embodiments of the present invention have been shown and described, it will be understood by those skilled in the art that it is not intended to limit the present invention to the preferred embodiments, and it will be obvious to those skilled in the art that various changes and modifications may be made without departing from the spirit and scope of the invention.

The scope of the present invention, therefore, is to be defined by the appended claims and equivalents thereof.

1. A thinner composition comprising:
a compound of formula (1);
an organic solvent with a Hansen solubility parameter by hydrogen bonding force (δh) value of 10 or more; and
a lactone-based organic solvent: 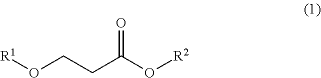
wherein,
R¹ and R² are each independently C₁-C₄ alkyl.

2. The thinner composition according to claim 1, wherein the compound of formula (1) is one or more selected from the group consisting of ethyl 3-methoxypropionate, propyl 3-methoxypropionate, butyl 3-methoxypropionate, ethyl 3-ethoxypropionate, propyl 3-ethoxypropionate, butyl 3-ethoxypropionate, ethyl 3-propoxypropionate, propyl 3-propoxypropionate, butyl 3-propoxypropionate, ethyl 3-butoxypropionate, propyl 3-butoxypropionate, and butyl 3-butoxypropionate.

3. The thinner composition according to claim 1, wherein the organic solvent with a Hansen solubility parameter by hydrogen bonding force (δh) value of 10 or more is one or more selected from the group consisting of propylene glycol methyl ether, 2-hydroxyisobutyric acid methyl ester, diethylene glycol monobutyl ether, diethylene glycol monoethyl ether, ethyl lactate, butanol, and N,N-dimethylformamide.

4. The thinner composition according to claim 1, wherein the lactone-based organic solvent is one or more selected from the group consisting of γ-butyrolactone, γ-valerolactone and ε-caprolactone.

5. The thinner composition according to claim 1, further comprising C₂-C₄ alkylene glycol C₁-C₄ alkyl ether acetate.

6. The thinner composition according to claim 5, wherein the C₂-C₄ alkylene glycol C₁-C₄ alkyl ether acetate is one or more selected from the group consisting of propylene glycol monomethyl ether acetate, propylene glycol monoethyl ether acetate, ethylene glycol monomethyl ether acetate, and ethylene glycol monoethyl ether acetate.

7. The thinner composition according to claim 1, comprising:
45 to 90 wt % of the compound of formula (1);
5 to 50 wt % of the organic solvent with a Hansen solubility parameter by hydrogen bonding force (δh) value of 10 or more; and
0.1 to 30 wt % of the lactone-based organic solvent.

8. The thinner composition according to claim 5, comprising:
45 to 90 wt % of the compound of formula (1);
5 to 50 wt % of the organic solvent with a Hansen solubility parameter by hydrogen bonding force (δh) value of 10 or more;
0.1 to 30 wt % of the lactone-based organic solvent; and
0.1 to 30 wt % of C₂-C₄ alkylene glycol C₁-C₄ alkyl ether acetate.

9. The thinner composition according to claim 1, wherein the thinner composition is for one or more of a photoresist film and a spin-on hardmask (SOH).

10. The thinner composition according to claim 9, wherein the photoresist film is a photoresist film for ArF, KrF, or EUV.
